(19) United States
(12) Patent Application Publication
(10) Pub. No.: US 2008/0179589 A1
(43) Pub. Date: Jul. 31, 2008

(54) SYSTEMS, DEVICES AND METHODS INVOLVING SUPERLATTICE INFRARED DETECTOR STRUCTURES

(75) Inventor: Stefan Per Svensson, Columbia, MD (US)

Correspondence Address: U S ARMY RESEARCH LABORATORY;ATTN AMSRL CS CC IP, 2800 POWDER MILL RD, ADELPHI, MD, 207831197, US

(73) Assignee: US Government as represented by Secretary of the Army, Adelphi, MD (US)

(21) Appl. No.: 12/060,931

(22) Filed: Apr. 2, 2008

Related U.S. Application Data
(63) Continuation-in-part of application No. 11/441,035, filed on May 26, 2006.
(60) Provisional application No. 60/685,042, filed on May 26, 2005.

(51) Int. Cl. H01L 29/06; H01L 21/02

(52) U.S. Cl. 257/21; 438/98; 257/E29.072; 257/E21.002

(57) ABSTRACT

Included are embodiments for providing an infrared detector structure. At least one embodiment of a device includes a substrate and an n-type layer coupled to the substrate, the n-type layer being configured as an n-type contact for a first electrical connection to a read out integrated circuit. Some embodiments include a growing component configured as an intrinsic absorbing superlattice and a p-type contact layer coupled to the intrinsic absorbing superlattice layer, the p-type contact layer being coupled to the read out integrated circuit via a second electrical connection.

### RELATED CASES

This application is related to and is a continuation-in-part of U.S. application Ser. No. 11/441,035 filed 2006-May-26 (ARL 05-44) which, in turn, claims benefit of Provisional Application 60/685,042 filed 2005-May-26.

### GOVERNMENT INTEREST

The invention described herein was made by or for the U.S. Government by Government employees and may be manufactured or used by or for the benefit of United States Government without license

### BACKGROUND

In infrared (IR) detector design, many read out integrated circuits (ROICs) are designed for detector structures that include a stack of positively doped layers on top and negatively doped layers on the bottom (p-on-n). ROICs with opposite polarity (n-on-p) are available, but may have significantly inferior performance for applications such as IR detectors. Additionally, type II superlattice detectors may be grown on nominally undoped (residual p-type) Gallium Antimonide (GaSb) substrates. Generally speaking, however, current detectors in the industry with GaSb substrates are configured as n-on-p detectors. As such, the ROICs associated with these detectors are either desired to be manufactured for this configuration, or adapted to support this configuration.

### SUMMARY

Included are embodiments for providing an infrared detector structure. At least one embodiment of a device includes a substrate, an n-type layer coupled to the substrate, a first portion of the n-type layer being configured as an n-type contact layer for a first electrical connection to a read out integrated circuit, a second portion of the n-type layer being configured as a bulk layer, and a p-type contact layer coupled to the bulk layer, the p-type contact layer being coupled to the read out integrated circuit via a second electrical connection.

Also included are embodiments of a method. At least one embodiment of a method includes growing an n-type layer on a substrate, a first portion of the n-type layer being configured as an n-type contact layer for a first electrical connection to a read out integrated circuit, a second portion of the n-type layer being configured as a bulk layer; and growing a p-type contact layer on the bulk layer, the p-type contact layer being coupled to the read out integrated circuit via a second electrical connection.

Also included are embodiments of a system. At least one embodiment of a system includes a first growing component configured to grow an n-type layer on a substrate, a first portion of the n-type layer being configured as an n-type contact layer for a first electrical connection to a read out integrated circuit, a second portion of the n-type layer being configured as a bulk layer and a second growing component configured to grow a p-type contact layer on the bulk layer, the p-type contact layer being coupled to the read out integrated circuit via a second electrical connection.

Other systems, methods, features, and/or advantages of this disclosure will be or may become apparent to one with skill in the art upon examination of the following drawings and detailed description. It is intended that all such additional systems, methods, features, and advantages be included within this description and be within the scope of the present disclosure.

### BRIEF DESCRIPTION

Many aspects of the disclosure can be better understood with reference to the following drawings. The components in the drawings are not necessarily to scale, emphasis instead being placed upon clearly illustrating the principles of the present disclosure. Moreover, in the drawings, like reference numerals designate corresponding parts throughout the several views. While several embodiments are described in connection with these drawings, there is no intent to limit the disclosure to the embodiment or embodiments disclosed herein. On the contrary, the intent is to cover all alternatives, modifications, and equivalents.

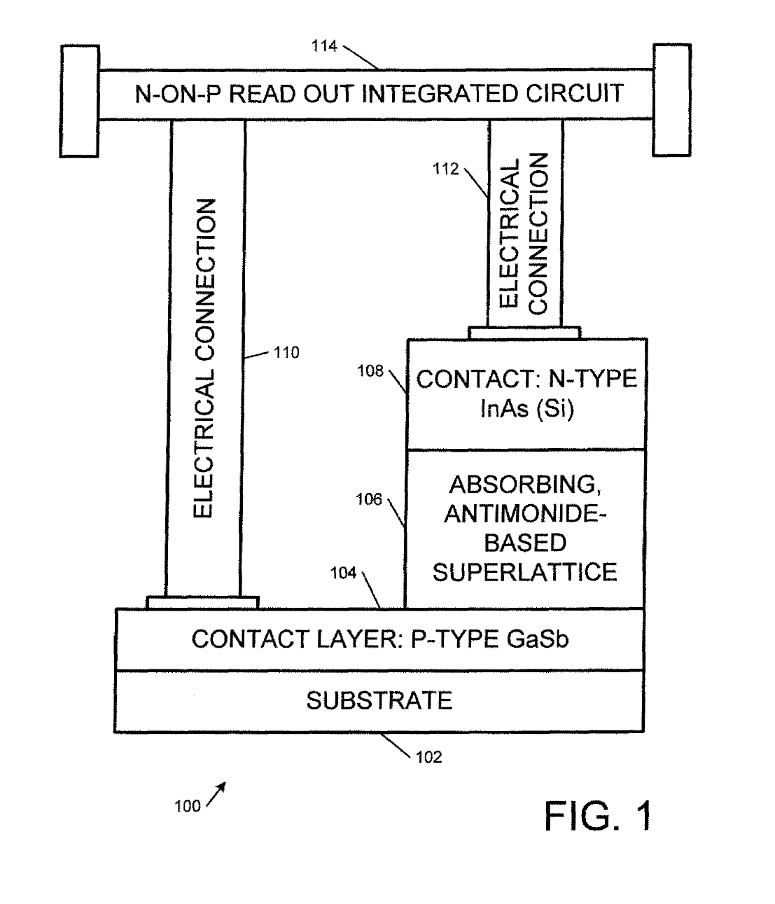

FIG. 1 is an embodiment of an n-on-p detector utilizing a Gallium Antimonide (GaSb) substrate.

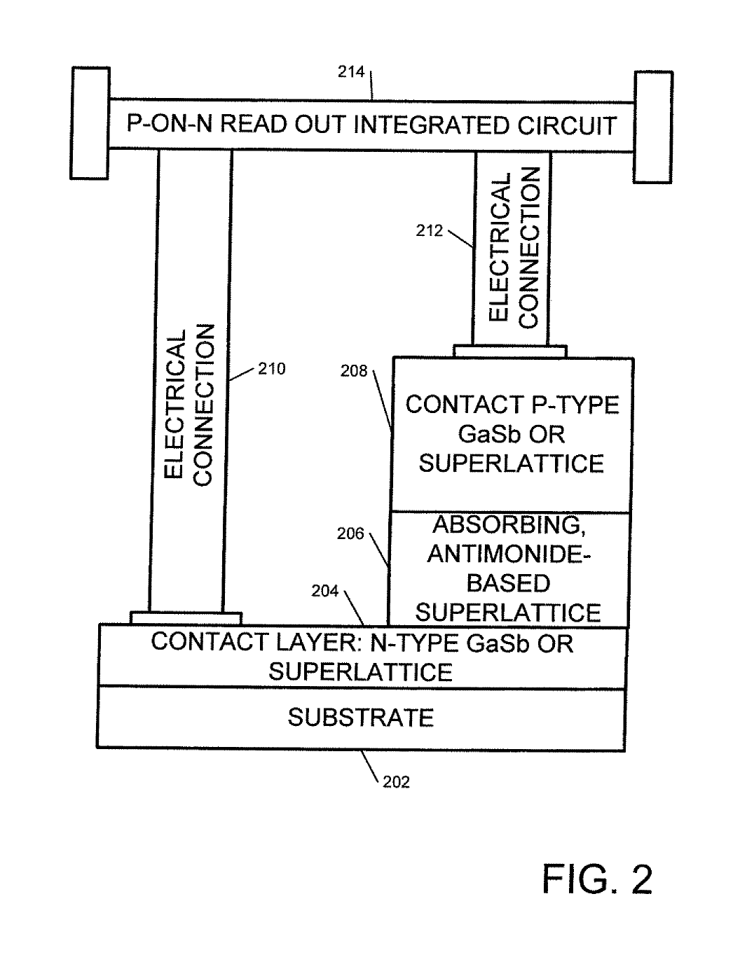

FIG. 2 is an embodiment of a p-on-n detector utilizing a Gallium Antimonide (GaSb) substrate, similar to the detector from FIG. 1.

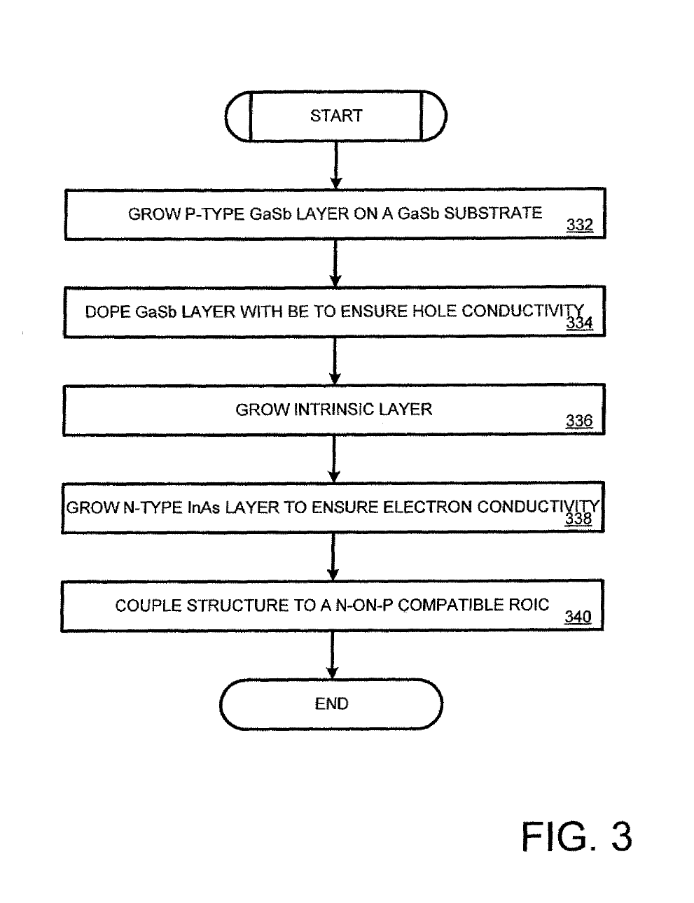

FIG. 3 is a flowchart illustrating an exemplary process that can be taken in creating an n-on-p structure, similar to the structure from FIG. 1.

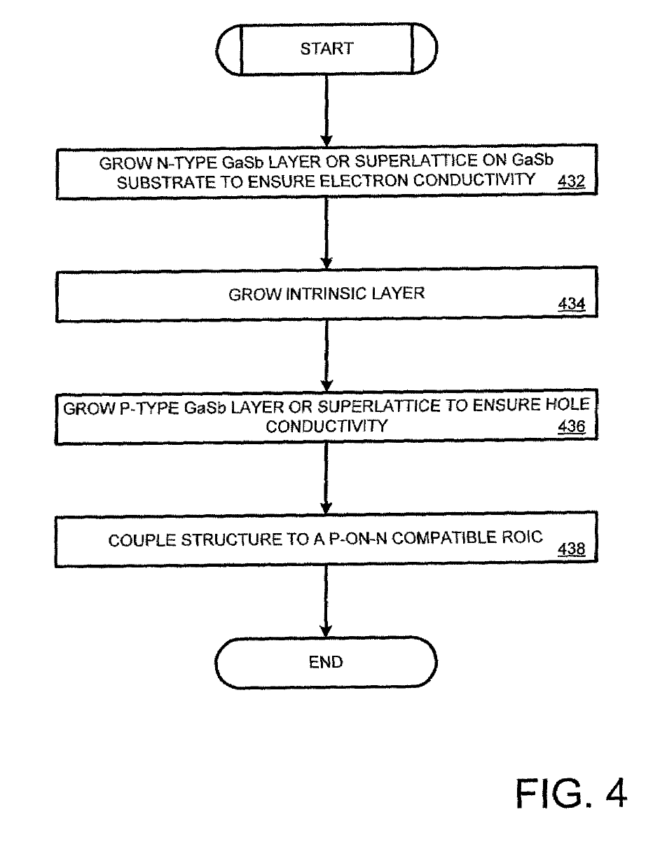

FIG. 4 is a flowchart illustrating an exemplary process that can be taken in creating a p-on-n structure, similar to the structure of FIG. 2.

### DETAILED DESCRIPTION

The vast majority of read out integrated circuits (ROICs) are designed for detector structures including a stack of positively doped layers on top, and negatively doped layers on the bottom (p-on-n). ROICs with opposite polarity are available, but may have significantly inferior performance. Type II superlattice detectors may be grown on nominally undoped (residual p-type) Gallium Antimonide (GaSb) substrates. Oftentimes, a doped GaSb layer may be grown on the GaSb substrate to form the lower contact for the photodiode. Molecular Beam Epitaxy (MBE) systems configured for growth of group III-V materials are almost exclusively equipped with Beryllium (Be) as a p-dopant material and Silicon (Si) as an n-dopant. Unfortunately, Si may not act as a donor (n-dopant) in GaSb. Beryllium (Be), on the other hand, will p-dope GaSb, making a bottom p-contact layer the logical choice. The top layer of opposite polarity can then be a thin layer of Indium Arsenide (InAs), which can be doped with Si. The thin InAs layer may be strained, but will not disturb the rest of the structure as long as it is sufficiently thin and deposited last in the layer stack. In principle, a similarly thin layer could be introduced at the bottom of the stack. However, there such a layer is more likely to disturb the quality of subsequent layers and by being very thin such a layer would be very difficult to reach with etching techniques and may provide an undesirable, high series resistance. Many published Type II Superlattice (SL) Infrared (IR) detector structures use the less advantageous n-on-p configuration.

By outfitting a crystal growth reactor with both a Be source for p-doping and a tellurim (Te) source or other group 6 element for n-doping in GaSb, the more desired p-on-n polarity can be produced. Since both doped layers would be unstrained GaSb, they could be grown as thick as necessary for ease of processing. Such has been disclosed in U.S. application Ser. No. 11/441,035, (Attorney Docket Number ARL 05-44) filed, May 26, 2006, which is hereby incorporated by reference in its entirety.

Embodiments of this disclosure include further simplification of the structure that relies on the observation that the light-absorbing superlattice itself has a smaller bandgap than either of the other two potential bulk contact materials, (e.g., GaSb and InAs). Materials with small bandgap may be utilized as contacting materials since they are easy to dope and provide small or no potential barriers between themselves and the active region material that they are connected to. In at least one embodiment, the bottom bulk contact is replaced with a superlattice material. This may include alternating layers of GaSb and Si-doped InAs. The resulting conductivity will be n-type. The thickness of the layers in the superlattice may be chosen such that they are thin enough to form conducting bands and designed to be nearly net-strain-free. A mid-infrared type II superlattice structure may use 24 Angstrom GaSb and 24 Angstrom InAs. Due to spontaneous interdiffusion interface components of GaAs and InSb may also form. For the purpose of strain determination, this can be modeled as an InSb layer with around 1.75 Angstrom thickness and no GaAs formation. The InSb thickness is subtracted from the design thickness of the InAs. In at least one embodiment, both GaAs and InSb may form, both of which are thicker than 1.75 Angstroms. However, they will produce opposite strains but of different magnitude so that the net effect equals that of 1.75 A InSb only. For the exemplified structure, the net strain will be around 8.8E-4. If needed, this can be reduced to zero by reducing the InAs thickness to around 18 Angstroms. The same contacting superlattice structure can be used together with an active region designed for any other wavelength and the contacting superlattice can be further modified to resemble the active region design if desirable.

An advantage of at least one embodiment included in this disclosure is that no modifications to the crystal growth reactor are required. No other dopants need to be introduced while the preferred detector polarity can still be realized. The use of a p-on-n ROIC with a Type II SL IR detector will allow for a larger range of detector biases due to higher charge well capacity. This in turn enables longer integration times for noise reduction and provides for a wider dynamic range in the image.

Referring to the drawings, FIG. 1 is an embodiment of an n-on-p detector utilizing a Gallium Antimonide (GaSb) substrate. This detector structure can be grown using a Molecular Beam Epitaxy (MBE) machine configured for standard group III-V semiconductor growth using beryllium (Be) for p-type doping and silicon (Si) for n-type doping. As illustrated in FIG. 1, a p-doped GaSb layer 104 can be grown on the GaSb substrate 102 to form the lower contact for the photodiode 100. For this embodiment, the top layer 108 of opposite polarity may include a thin layer of Indium Arsenide (InAs), which can be doped with Si. The thin InAs layer 108 may be strained, but will not generally disturb the rest of the structure as long as the InAs is sufficiently thin and deposited last in the layer stack. Such a configuration provides the n-on-p detector configuration discussed above.

Additionally, a similarly thin layer of InAs can be introduced at the bottom of the stack for layer 104, when this occurs, the InAs may disturb the quality of subsequent layers (106, 108) and by being very thin, the InAs may be very difficult to reach with etching techniques. Further, using InAs for layer 104 may provide an undesirable, high series resistance. Thus, many current techniques of creating a p-on-n detector configuration have been difficult to realize.

As suggested above, the detector material structure of FIG. 1 can be constructed with an intentionally undoped superlattice (such as 24 Å InAs/24 Å GaSb, however this is a nonlimiting example) with a p-doped GaSb bottom contact and a pseudomorphic n-doped InAs top contact layer. This structure can be configured to provide a predetermined conduction miniband energy width and a cutoff wavelength in the range of about 2 microns to greater than about 30 microns. The structure may also include an etch release layer of Aluminum Gallium Antimonide (AlGaSb) to allow for the removal of the GaSb substrate after the processed detector array is bonded to the ROIC.

FIG. 2 is an embodiment of a p-on-n detector utilizing a Gallium Antimonide (GaSb) substrate, similar to the detector from FIG. 1. As illustrated in this nonlimiting example, a superlattice material may be utilized to provide the bottom bulk (intrinsic) layer 204. More specifically, alternating layers of GaSb and Si-doped InAs may be applied to a GaSb substrate 202. As such, the resulting conductivity may be n-type. An absorbing, antimonide-based superlattice 206 may be applied to a portion of the contact layer 204. Additionally, a p-type GaSb (or superlattice) contact layer 208 can then be applied to the antimonide-based superlattice absorbing layer 206. Electrical connections 210 and 212 can be coupled to the n-type GaSb contact layer 204 and the p-type GaSb contact layer 208, respectively. The electrical connections 210 and 212 can also be coupled to a p-on-n ROIC 214. Application of the components described above can include the introduction in an MBE machine of an additional evaporation source to be loaded with tellurium (Te), which is known to be an n-type dopant in GaSb.

One should note that, in at least one embodiment, the use of a p-on-n ROIC with a Type II superlattice infrared detector can allow for a larger range of detector biases due to higher charge well capacity. This may provide longer integration times for noise reduction and provides for a wider dynamic range in a captured image.

FIG. 3 is a flowchart illustrating an exemplary process that can be taken in creating an n-on-p structure, similar to the structure from FIG. 1. As illustrated in this nonlimiting example a GaSb layer may be grown on a GaSb substrate (block 332). As discussed above, this block (as well as other blocks) can be performed with the utilization of an MBE machine. Next, the GaSb layer can be positively doped with Be to make GaSb layer p-type and to ensure hole conductivity (block 334). Next, the intrinsic (undoped) layer can be grown (block 336). Once the intrinsic layer is grown, a layer of negatively doped InAs can be grown to ensure electron conductivity (block 338). The created structure can then be coupled to an n-on-p compatible integrated circuit (block 340).

FIG. 4 is a flowchart illustrating an exemplary process that can be taken in creating a p-on-n structure, similar to the structure of FIG. 3. As illustrated in the nonlimiting example of FIG. 4, a GaSb layer or superlattice may be grown on a GaSb substrate to ensure electron conductivity (block 432). An intrinsic (undoped) layer can then be grown (block 434). After this, a p-type GaSb layer (or a superlattice) can be grown to ensure hole conductivity (block 436). The structure can then be coupled to a p-on-n compatible integrated circuit (block 438).

One should note that the flowcharts included herein show the architecture, functionality, and operation of a possible implementation. In this regard, each block can be interpreted to represent a module, or segment for implementing the specified function(s). It should also be noted that in some implementations, the functions noted in the blocks may occur out of the order and/or not at all. For example, two blocks shown in succession may in fact be executed substantially concurrently or the blocks may sometimes be executed in the reverse order, depending upon the functionality involved.

One should note that any of the functions described herein can be embodied in any computer-readable medium for use by or in connection with an instruction execution system, apparatus, or device, such as a computer-based system, processor-containing system, or other system that can fetch the instructions from the instruction execution system, apparatus, or device and execute the instructions. In the context of this document, a “computer-readable medium” can be any means that can contain, store, communicate, or transport the program for use by or in connection with the instruction execution system, apparatus, or device. The computer readable medium can be, for example but not limited to, an electronic, magnetic, optical, electromagnetic, infrared, or semiconductor system, apparatus, or device. More specific examples (a nonexhaustive list) of the computer-readable medium could include an electrical connection (electronic) having one or more wires, a portable computer diskette (magnetic), a random access memory (RAM) (electronic), a read-only memory (ROM) (electronic), an erasable programmable read-only memory (EPROM or Flash memory) (electronic), an optical fiber (optical), and a portable compact disc read-only memory (CDROM) (optical). In addition, the scope of the certain embodiments of this disclosure can include embodying the functionality described in logic embodied in hardware or software-configured mediums.

One should also note that conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more particular embodiments or that one or more particular embodiments necessarily include logic for deciding, with or without user input or prompting, whether these features, elements and/or steps are included or are to be performed in any particular embodiment.

It should be emphasized that the above-described embodiments are merely possible examples of implementations, merely set forth for a clear understanding of the principles of this disclosure. Many variations and modifications may be made to the above-described embodiment(s) without departing substantially from the spirit and principles of the disclosure. All such modifications and variations are intended to be included herein within the scope of this disclosure.

Therefore, at least the following is claimed:

1. A method for providing an infrared detector structure, comprising:
growing an n-type layer on a substrate, the n-type layer being configured as an n-type contact layer for a first electrical connection to a read out integrated circuit, with an intrinsic absorbing superlattice; and
growing a p-type contact layer directly on the intrinsic absorbing superlattice layer, the p-type contact layer being coupled to the read out integrated circuit via a second electrical connection.

2. The method of claim 1, wherein the substrate is a Gallium Antimonide (GaSb) substrate.

3. The method of claim 1, wherein the n-type layer includes n-type Gallium Antimonide (GaSb).

4. The method of claim 1, wherein the n-type layer includes alternating layers of Gallium Antimonide (GaSb) and Silicon doped Indium Arsenide (InAs).

5. The method of claim 1, wherein the p-type contact layer includes Gallium Antimonide (GaSb).

6. The method of claim 1, wherein the n-type layer includes a superlattice.

7. The method of claim 1, wherein the read out integrated circuit is a p-on-n read out integrated circuit.

8. A system for providing an infrared detector structure, comprising:
a first growing component configured to grow an n-type layer on a substrate, the n-type layer being configured as an n-type contact layer for a first electrical connection to a read out integrated circuit;
a second growing component configured as an intrinsic absorbing superlattice; and
a third growing component configured to grow a p-type contact layer on the intrinsic absorbing superlattice, the p-type contact layer being coupled to the read out integrated circuit via a second electrical connection.

9. The system of claim 8, wherein the substrate is a Gallium Antimonide (GaSb) substrate.

10. The system of claim 8, wherein the n-type layer includes n-type Gallium Antimonide (GaSb).

11. The system of claim 8, further comprising means for alternating layers of Gallium Antimonide (GaSb) and Silicon doped Indium Arsenide (InAs) to provide the n-type layer.

12. The system of claim 8, wherein the p-type contact layer includes Gallium Antimonide (GaSb).

13. The system of claim 8, wherein the n-type layer includes a superlattice.

14. The system of claim 8, wherein the read out integrated circuit is a p-on-n read out integrated circuit.

15. A device for providing an infrared detector structure, comprising:
a substrate;
an n-type layer coupled to the substrate, the n-type layer being configured as an n-type contact for a first electrical connection to a read out integrated circuit;
a growing component configured as an intrinsic absorbing superlattice; and
a p-type contact layer coupled to the intrinsic absorbing superlattice layer, the p-type contact layer being coupled to the read out integrated circuit via a second electrical connection.

16. The device of claim 15, wherein the substrate is a Gallium Antimonide (GaSb) substrate.

17. The device of claim 15, wherein the n-type layer includes n-type Gallium Antimonide (GaSb).

18. The device of claim 15, wherein the n-type layer includes alternating layers of Gallium Antimonide (GaSb) and Silicon doped Indium Arsenide (InAs).

19. The device of claim 15, wherein the p-type contact layer includes Gallium Antimonide (GaSb).

20. The device of claim 15, wherein the n-type layer includes a superlattice.
